(19) United States
(12) Patent Application Publication
(10) Pub. No.: US 2025/0182822 A1
(43) Pub. Date: Jun. 5, 2025

(54) NEUROMORPHIC DEVICE AND OPERATION METHOD THEREOF

(71) Applicant: SEOUL NATIONAL UNIVERSITY R&DB FOUNDATION, Seoul (KR)

(72) Inventors: Woo Young CHOI, Seoul (KR); Jae Seung WOO, Seoul (KR)

(73) Assignee: SEOUL NATIONAL UNIVERSITY R&DB FOUNDATION, Seoul (KR)

(21) Appl. No.: 18/796,752

(22) Filed: Aug. 7, 2024

(30) Foreign Application Priority Data
Nov. 30, 2023 (KR) 10-2023-0171646
May 28, 2024 (KR) 10-2024-0069309

(51) Int. Cl. G11C 11/54; G11C 11/40

(52) U.S. Cl. CPC G11C 11/54; G11C 11/40

(57) ABSTRACT

A neuromorphic device includes: a plurality of bit lines; a plurality of word lines; and a non-volatile memory array including an ambipolar transistor disposed in a region where the bit lines and the word lines intersect. The non-volatile memory array uses the ambipolar transistor as a synaptic device. The non-volatile memory array performs two-layer operation by implanting different weights in two current regions present in the ambipolar transistor. The non-volatile memory array alternately applies specific voltages of first and second polarities to word lines and bit lines connected to specific synaptic devices among the plurality of bit lines and the plurality of word lines to perform weight implantation for multi-layer learning.

### CROSS-REFERENCE TO PRIOR APPLICATIONS

This application claims priority to Koran Patent Application Nos. 10-2023-0171646 (filed on Nov. 30, 2023) and 10-2024-0069309 (filed on May 28, 2024), which are all hereby incorporated by reference in their entirety.

### ACKNOWLEDGEMENT

### [National Research Development Project Supporting the Present Invention]

[Project Serial No.] 1711158813
[Project No.] 2021M3F3A2A01037927
[Department] Ministry of Science and ICT, Republic of Korea
[Project Management (Professional) National Research Foundation of Korea
[Research Project Name] Development of Next-generation Intelligent Semiconductor Technology (Devices)
[Research Task Name] Neuron circuit development for optimal SNN operation with synaptic device
[Project Performing Institute] Seoul National University R&DB Foundation
[Research Period] 2021.04.09 to 2023.12.31

### [National Research Development Project Supporting the Present Invention]

[Project Serial No.] 1711186719
[Project No.] 2022M317A1078544
[Department] Ministry of Science and ICT, Republic of Korea
[Project Management (Professional) Institute] National Research Foundation of Korea
[Research Project Name] PIM Artificial Intelligence Semiconductor Core Technology Development (Devices)
[Research Task Name] Development of silicon-based PIM-specific devices, circuits, and application technologies
[Project Performing Institute] Seoul National University R&DB Foundation
[Research Period] 2022.04.20 to 2024.12.31

### BACKGROUND

The present disclosure relates to a neuromorphic hardware structure, and more specifically, to a neuromorphic device capable of performing multi-layer artificial neural network computations in a single non-volatile memory array using the characteristics of an ambipolar transistor, and an operation method thereof.

Recently, as deep learning technology has developed dramatically, the amount of data and number of layers required for learning and running neural networks are rapidly increasing. Parallel computing circuits such as GPU (Graphics Processing Unit) are used to process large amounts of data. However, as a lot of power is generated in data communication, the need for semiconductor devices capable of more efficient neural network computations is rapidly increasing.

Since existing hardware operates based on the switching operation of logic elements, it is not suitable for performing neural network operations that require parallel multiple computations. In addition, due to the limitations of the Von Neumann structure, intensive data movement between memory and processor is a major cause of speed and energy efficiency degradation.

For large-scale parallel computing, neuromorphic hardware of various structures, such as SRAM (Static Random Access Memory) and RRAM (Resistive RAM), has been proposed. However, due to very low memory density and low technology maturity, it is difficult to achieve high precision and low power characteristics simultaneously. In addition, the need for circuits such as ADC (Analog-to-Digital Converter) to convert the results of analog parallel computations results in additional area and power consumption in terms of overall hardware, which provides no significant performance and power efficiency compared to existing digital parallel computations. Therefore, it is most important to reduce the amount of driving circuits such as ADC.

### SUMMARY

One embodiment of the present disclosure provides a neuromorphic device capable of performing two-layer operation with one array in a multi-layer artificial neural network computation by applying an ambipolar transistor-based non-volatile memory device in which two current mechanisms exist in one device, and an operation method thereof.

One embodiment of the present disclosure provides a neuromorphic device that can be configured in a much smaller area than existing neuromorphic hardware, and that can significantly increase power efficiency by reducing the number of ADCs for sensing output values, which accounts for the most power consumption in the computation of neuromorphic hardware by half, and an operation method thereof.

In accordance with one embodiment of the present disclosure, there is provided a neuromorphic device comprising: a plurality of bit lines; a plurality of word lines; and a non-volatile memory array including an ambipolar transistor disposed in a region where the bit lines and the word lines intersect.

The non-volatile memory array may use the ambipolar transistor as a synaptic device.

The non-volatile memory array may perform two-layer operation by implanting different weights in two current regions present in the ambipolar transistor.

The non-volatile memory array may alternately applies specific voltages of first and second polarities to word lines and bit lines connected to specific synaptic devices among the plurality of bit lines and the plurality of word lines to perform weight implantation for multi-layer learning.

The non-volatile memory array may apply a specific voltage of a first polarity to a forward region of the ambipolar transistor, and apply a specific voltage of a second polarity different from the first polarity to an ambipolar region of the ambipolar transistor to implant different weights in the respective regions.

The non-volatile memory array may perform weight implantation by applying a specific voltage to a word line and a bit line connected to a target device among the plurality of bit lines and the plurality of word lines, and allowing the remaining word lines and bit lines to be grounded or floating.

In accordance with one embodiment of the present disclosure, there is provided a multi-layer artificial neural network processing neuromorphic device, which comprises: a plurality of bit lines arranged to extend along a first direction; a plurality of word lines extending along a second direction perpendicular to the first direction; and a plurality of synaptic devices located in regions where the bit lines and the word lines intersect, wherein the synaptic device includes an ambipolar transistor composed of two current regions.

The ambipolar transistor may include a tunneling transistor or a ferroelectric tunneling transistor.

The ambipolar transistor may have two or more different current mechanisms depending on a gate voltage, and may include a forward region and an ambipolar region with symmetrical current characteristics as a function of voltage.

In one embodiment, in a non-volatile memory device based on the ambipolar transistor, the forward region and the ambipolar region may be each controlled to store two weights in one synaptic device.

In one embodiment, when different weights are stored in the forward region and the ambipolar region, two analog vector matrix multiplications (VMM) are performed in one synapse array.

In accordance with one embodiment of the present disclosure, there is provided an operation method of a neuromorphic device using an ambipolar transistor disposed in an array of non-volatile memory formed along a plurality of bit lines and a plurality of word lines, the method comprising: implanting a first weight in a first region of the ambipolar transistor; implanting a second weight in a second region of the ambipolar transistor; performing a first layer operation using a current in the first region and the implanted first weight; and performing a second layer operation using a current in the second region and the implanted second weight.

The ambipolar transistor may have two or more different current mechanisms depending on a gate voltage, and may include a forward region and an ambipolar region with symmetrical current characteristics as a function of voltage.

The implanting of the first weight may include applying a specific voltage of a first polarity to a gate of the ambipolar transistor to perform weight implantation in one of a forward region and an ambipolar region of the ambipolar transistor.

The implanting of the second weight may include applying a specific voltage of a second polarity to the gate of the ambipolar transistor to perform weight implantation in the remaining region of the ambipolar transistor.

In the implanting of the first weight and the implanting of the second weight, two weights may be stored in one synaptic device by controlling a forward region and an ambipolar region of the ambipolar transistor.

The performing of the first layer operation may include calculating with a weight of a forward region of the ambipolar transistor and adjusting a magnitude of an input signal through a voltage time Tₚᵤₗₛₑ applied to a gate of the ambipolar transistor.

The performing of the second layer operation may include calculating with a weight of an ambipolar region of the ambipolar transistor and adjusting a magnitude of an input signal through a voltage time Tₚᵤₗₛₑ applied to the gate of the ambipolar transistor.

The performing of the first layer operation and the second layer operation may include performing a product operation of weight and voltage by reading a current in the forward region and the ambipolar region of the ambipolar transistor.

The performing of the first layer operation and the second layer operation may obtain an operation result by sensing a current through an analog-to-digital converter (ADC).

The present disclosure exhibits the following effects. However, it is not intended to mean that a specific embodiment should include all of the following effects or only the following effects, the scope of the present disclosure should not be understood as being limited thereby.

The neuromorphic device and its operating method according to one embodiment of the present disclosure can perform two-layer operation with one array in a multi-layer artificial neural network computation by applying an ambipolar transistor-based non-volatile memory device in which two current mechanisms exist in one device.

The neuromorphic device and its operating method according to one embodiment of the present disclosure can be configured in a much smaller area than existing neuromorphic hardware, and can significantly increase power efficiency by reducing the number of ADCs for sensing output values, which accounts for the most power consumption in the computation of neuromorphic hardware by half.

### BRIEF DESCRIPTION OF THE DRAWINGS

FIG. 1 is a diagram for explaining the structure and operation method of neuromorphic hardware.

FIG. 2 is a diagram showing a neuromorphic hardware structure for multi-layer artificial neural network operation using existing MOSFET-based NVM.

FIGS. 3A to 3C are diagrams for explaining a neuromorphic device according to one embodiment of the present disclosure.

FIG. 4 is a diagram for explaining a weight implantation operation of the neuromorphic device according to one embodiment of the present disclosure.

FIGS. 5A and 5B are diagrams for explaining an embodiment using a FeTFET device.

FIG. 6 is a diagram for explaining a neuromorphic hardware structure according to one embodiment of the present disclosure.

FIG. 7 is a diagram showing individual weight measurement results by two current mechanisms of an ambipolar transistor.

FIGS. 8A to 8C are diagrams for explaining a neuromorphic hardware structure and operation method according to one embodiment of the present disclosure.

### DETAILED DESCRIPTION

The description of the present disclosure is only an embodiment for structural or functional explanation, the scope of the present disclosure should not be construed as limited by the embodiment described herein. In other words, since the embodiment can be modified in various ways and can have various forms, the scope of the present disclosure should be understood to include equivalents that can realize the technical idea. In addition, the objects or effects presented in the present specification does not mean that a specific embodiment should include all of them or only those effects, so the scope of the present disclosure should not be understood to be limited thereby.

Meanwhile, the meaning of the terms described in the present specification should be understood as follows.

The terms such as “first,” “second,” etc. are used to distinguish one component from another, and the scope of the present disclosure should not be limited by these terms. For example, a first component may be named a second component, and similarly, the second component may also be named the first component.

When a component is referred to as being “connected” to another component, it should be understood that it may be directly connected to the other component, but that other components may also exist between them. On the other hand, when a component is referred to be as being “directly connected” to another component, it should be understood that there are no other components between them. Meanwhile, other expressions that describe the relationship between components, such as “between” and “immediately between” or “adjacent to” and “directly adjacent to”, should be interpreted similarly.

Singular expressions should be understood to include plural expressions unless the context clearly indicates otherwise, and the terms such as “include” or “have” are intended to designate that the presence of a features, number, step, operation, component, part, or combination thereof, and should be understood as not excluding in advance the possibility of the presence or addition of one or more other features, numbers, steps, operations, components, parts, or combinations thereof.

For each step, identification codes (e.g., a, b, c, etc.) are used for convenience of explanation. The identification codes do not describe the order of steps, and the steps may occur in any order other than that specified unless the context clearly indicates a specific order. That is, the steps may occur in the same order as specified, may be performed substantially simultaneously, or may be performed in the opposite order.

All terms used herein, unless otherwise defined, have the same meaning as commonly understood by a person of ordinary skill in the field to which the present disclosure pertains. The terms defined in commonly used dictionaries should be interpreted as consistent with the their meaning in the context of the related art, and are not to be interpreted as having an idealized or unduly formal meaning unless expressly defined in the present specification.

Hereinafter, with reference to the accompanying drawings, preferred embodiments of the present disclosure will be described in more detail. In the description of the present disclosure, the same reference numerals are used for the same components in the drawings, and redundant descriptions of the same components are omitted.

As artificial intelligence technology develops further, more data computations are essential for artificial intelligence computations. However, existing computing methods have a bottleneck between the processor and memory, resulting in slow processing speed and high power consumption during artificial intelligence computations. Although various technologies have been reported to reduce this bottleneck, innovation in hardware structure is necessary because there are fundamental limitations to the bottleneck. Among them, neuromorphic hardware, which implements artificial neural networks using the basic physical phenomena of circuits, is gaining attention.

The neuromorphic hardware has attracted attention as a next-generation technology because it can dramatically reduce the computation speed and power compared to conventional computing hardware by utilizing the analog parallel computation characteristics of devices, and researchers are continuously conducting research to implement neuromorphic hardware using various non-volatile memory devices (NVMs). Parallel computation of matrix products is the most important in artificial intelligence computations, and neuromorphic hardware enables parallel computation of matrix products by training analog weights on non-volatile memory devices and then activating the devices simultaneously. However, since the computation is performed at the analog level, it is important to convert the obtained results into digital to perform additional computations that are important in artificial neural networks, such as activation and batch normalization. Circuitry such as an analog-to-digital converter (ADC) is necessary for this, and this additional circuitry requires additional power and processing time. In addition, when the array is small due to the complexity of the circuitry, the area occupied by the ADC is relatively large, which significantly reduces the computational efficiency per area.

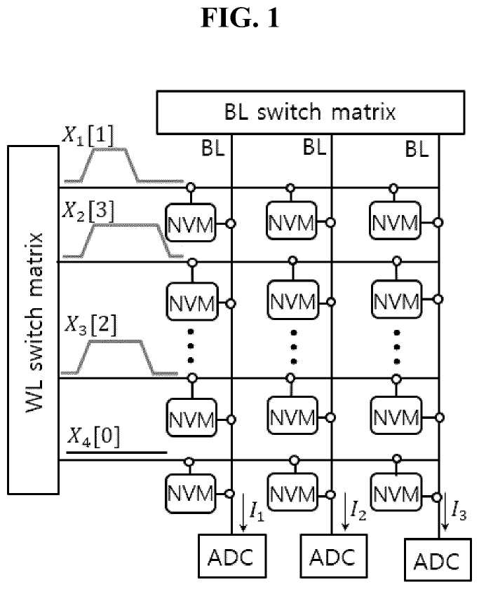

FIG. 1 is a diagram for explaining the structure and operation method of neuromorphic hardware, and represents a typical operation method of an artificial neural network operation in neuromorphic hardware.

As shown in FIG. 1, when an input signal is given using the PWM (pulse width modulation) method, the NVM (non-volatile memory) device is turned on, and the output of each line is obtained by sensing the current in the ADC. In this case, the weight matrices stored in transconductance and conductance formats of the NVM are simultaneously multiplied with word line voltage signal X and output as bit line current I to perform a massively parallel computation.

The ADC consumes the most power during neuromorphic computation, and additionally, occupies a lot of area due to the complexity of the circuit. Therefore, neuromorphic hardware using conventional NVM devices uses a lot of energy during computation.

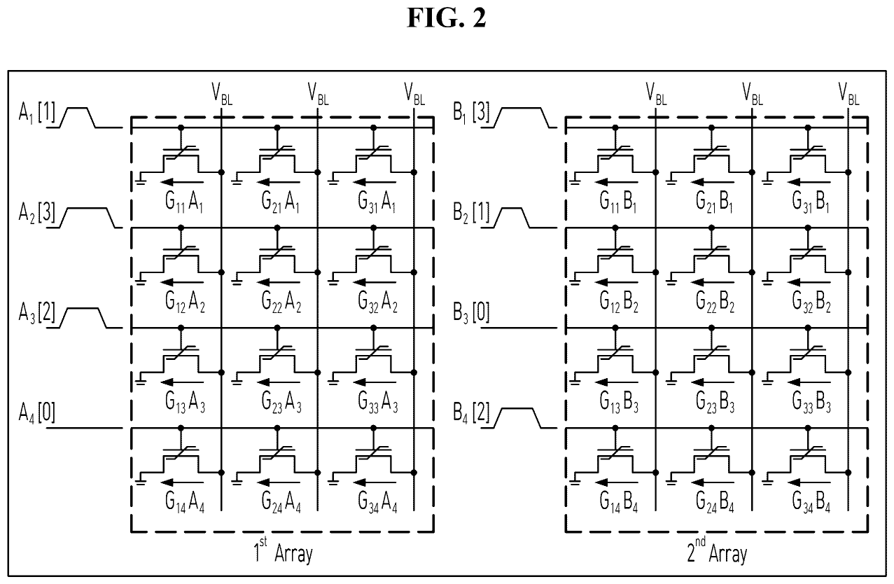

FIG. 2 is a diagram showing a neuromorphic hardware structure for multi-layer artificial neural network operation using existing MOSFET-based NVM.

As shown in FIG. 2, most non-volatile memories used in existing neuromorphic devices implant only one weight from one synaptic device. In other words, NVM-based neuromorphic hardware structures such as MOSFETs require multiple arrays (1st Array, 2nd Array) with different weights learned for multi-layer artificial neural network operations. In this case, due to the increase in the number of arrays, an increase in the required chip area and an increase in the driving circuit is inevitable, so there is a limit to TOPs/W and TOPs/mm², which are essential for low-power neuromorphic hardware. In addition, due to the high current characteristics, there is a limit to the array size.

Accordingly, the present disclosure proposes a neuromorphic hardware structure and operation method capable of multi-layer artificial neural network operations using an ambipolar transistor-based NVM device in which two current mechanisms exist in one device. Through this, the chip area can be dramatically reduced and the number of driving circuits can be reduced by more than half, allowing for more efficient artificial neural network operations.

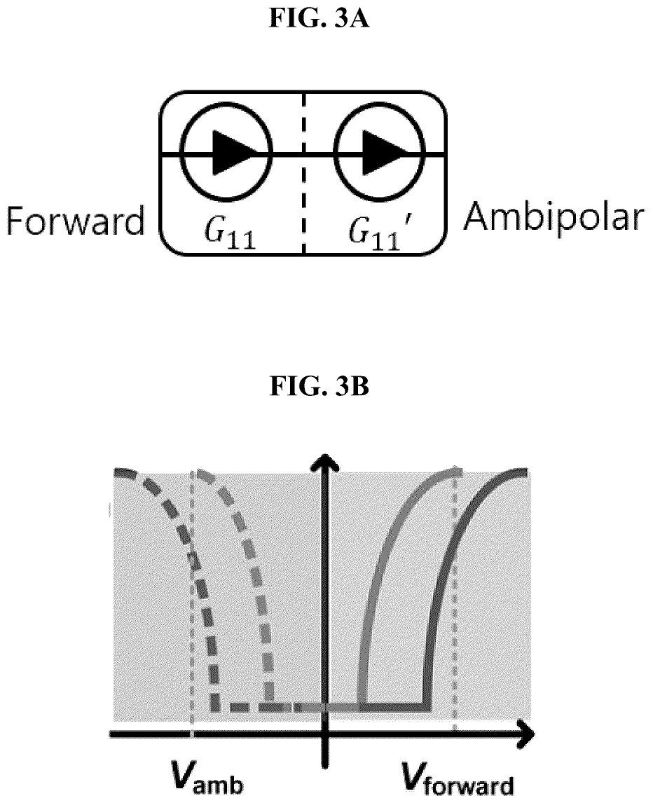

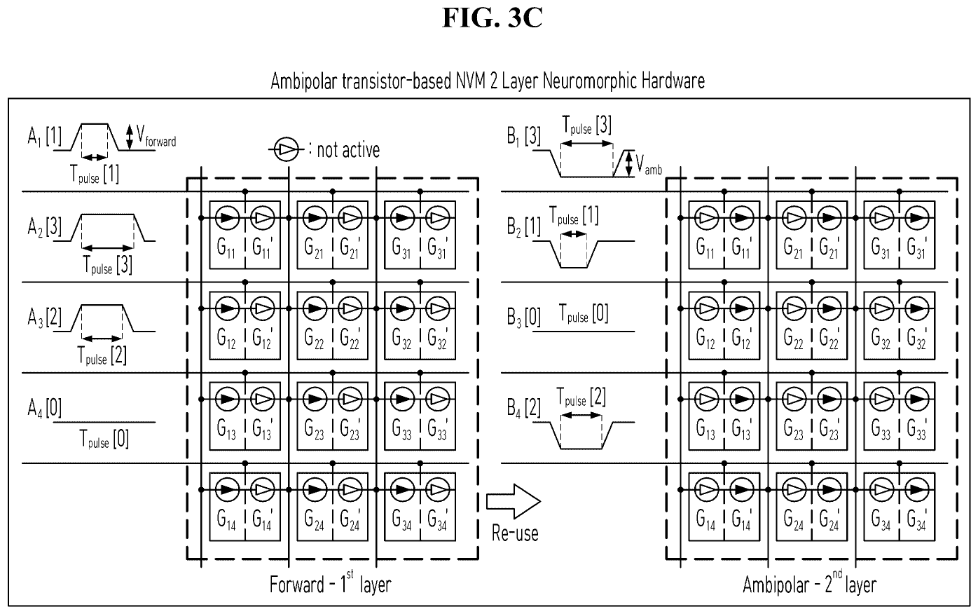

FIGS. 3A to 3C are diagrams for explaining a neuromorphic device according to one embodiment of the present disclosure, and are diagrams for explaining multi-layer artificial neural network processing neuromorphic hardware using an ambipolar transistor.

First, FIG. 3A shows a conceptual diagram of an ambipolar transistor-based non-volatile memory. Unlike metal oxide semiconductor field effect transistors (MOSFETs), ambipolar transistors can usually be composed of a forward region and an ambipolar region with symmetrical current characteristics as a function of voltage since there are two or more different current mechanisms depending on the gate voltage. Using these characteristics, an ambipolar transistor-based NVM can store two independent weights in one device as shown in FIG. 3B by controlling the two current mechanisms differently. In this case, by implanting different weights in two different current regions, two analog vector matrix multiplications (VMM) are possible in one synapse array. Therefore, by using one ambipolar transistor-based NVM array storing two independent weights as shown in FIG. 3C, a neuromorphic hardware structure capable of two artificial neural network operations can be realized. In this case, the ambipolar transistor may include a tunneling transistor or a ferroelectric tunneling transistor, but is not necessarily limited thereto.

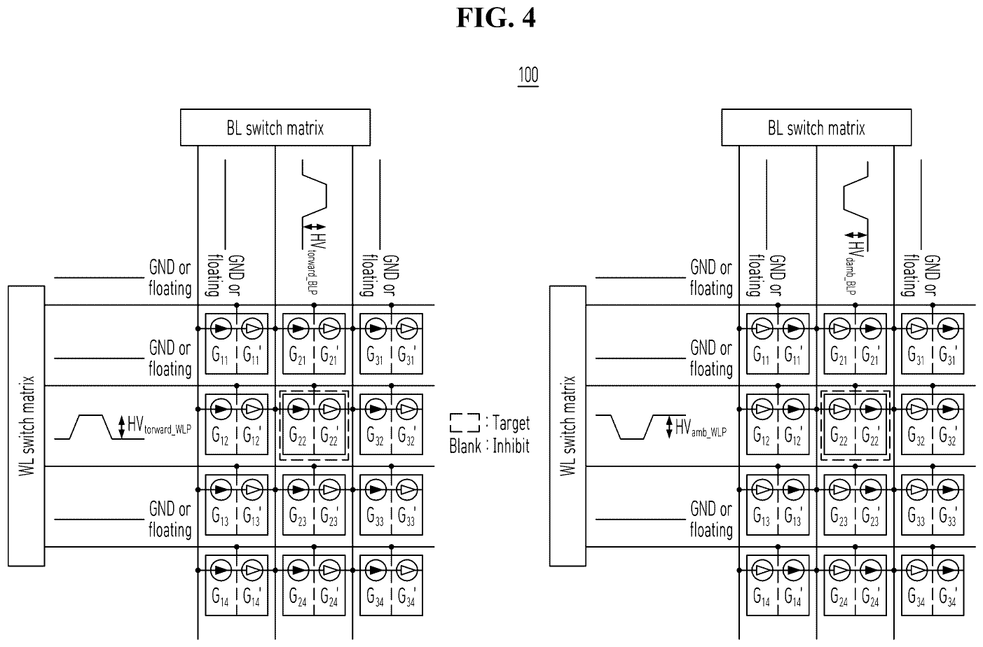

FIG. 4 is a diagram for explaining a weight implantation operation of the neuromorphic device according to one embodiment of the present disclosure.

Referring to FIG. 4, the neuromorphic device 100 may be configured as an array of non-volatile memory (NVM) formed along a plurality of bit lines (BL) and a plurality of word lines (WL). The neuromorphic device 100 may include a non-volatile memory array including ambipolar transistors disposed in regions where the bit lines and the word lines intersect. In this case, the non-volatile memory array may use ambipolar transistors as synaptic se devices. For multi-layer computation, it is most important to implant two different weights in ambipolar transistor-based non-volatile memory (NVM). That is, the neuromorphic device 100 can perform two-layer operation by implanting different weights in two current regions existing in the ambipolar transistor. At this time, weight implantation may be performed in a similar manner to an existing NOR or AND type array. Specifically, the neuromorphic device 100 may perform weight implantation for multi-layer learning by alternately applying specific voltages of first and second polarities to the word line and the bit line connected to a specific synaptic device among the plurality of bit lines and the plurality of word lines. The neuromorphic device 100 can apply a specific voltage of the first polarity to the forward region of the ambipolar transistor and a specific voltage of the second polarity different from the first polarity to the ambipolar region of the ambipolar transistor to implant different weights in the respective regions.

For example, as shown in FIG. 4, the transconductance or conductance of the forward region can be adjusted by applying a high voltage to the word line and bit line connected to a target device where weight implantation is desired. The remaining word lines and bit lines are grounded (GND) or floating. In addition, for the weights in the ambipolar region, the transconductance or conductance can be adjusted by applying a higher voltage of a different polarity than the weight implantation in the forward region. In this case, the polarity of the voltage may be reversed depending on the material storing the weights.

For example, in the case of a charge storage type memory, when a negative weight is implanted in the forward region, this can be done by applying a strong positive voltage to the word line WL and bit line BL. When implanting a negative weight in the ambipolar region, this can be done by applying a strong negative voltage to the word line WL and a strong positive voltage to the bit line BL.

In contrast, in the case of a ferroelectric memory, when a positive weight is implanted in the forward region, this can be done by applying a strong positive voltage to the word line WL and bit line BL, and when a positive weight is implanted in the ambipolar region, this can be done by applying a strong negative voltage to the word line WL and a strong positive voltage to the bit line BL. In addition, as with the AND type array, weight implantation is also possible through floating the word line and bit line.

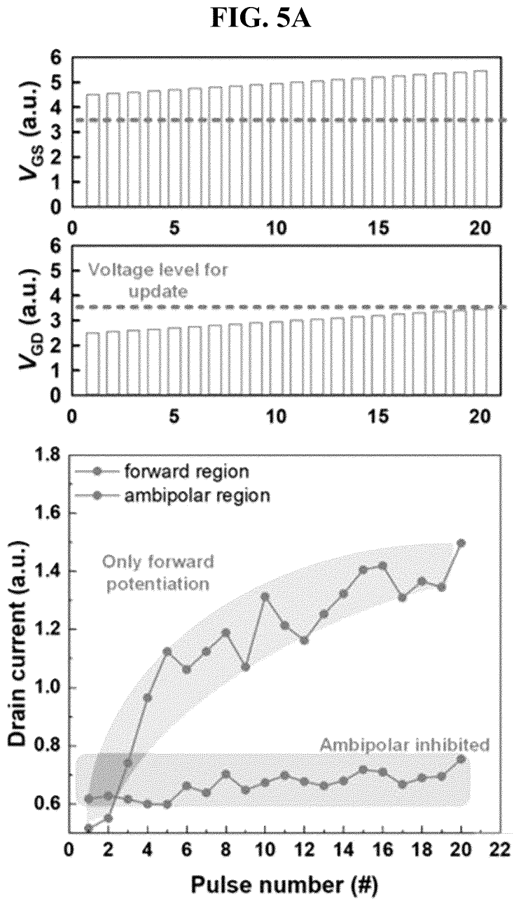

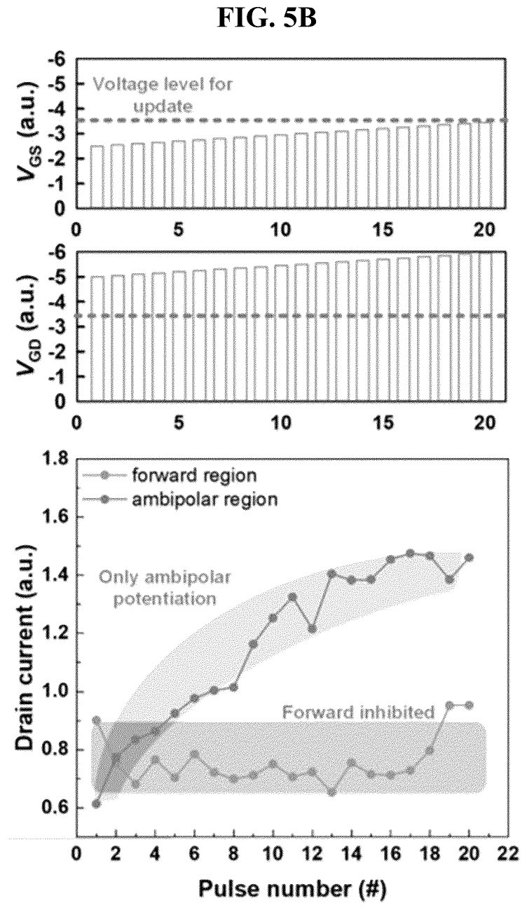

FIGS. 5A and 5B are diagrams for explaining an embodiment using a FeTFET device.

Referring to FIGS. 5A and 5B, it is explained that in ferroelectric memory, the forward region or ambipolar region can be adjusted by applying voltages to the word line and bit line using the ISPP (Incremental Step Pulse Program) method. In this case, the ISPP method refers to the method of subdividing the voltage and increasing the voltage in small steps.

Referring to FIGS. 5A and 5B, it can be seen that the forward region or ambipolar region can be adjusted through the difference Vos between the gate voltage and the source voltage or the difference V_{GD} between the gate voltage and the drain voltage of the device to be updated for weight.

FIG. 5A is a graph for explaining controlling only the forward region of the device for which weight implantation is desired. In this case, only the forward region of the device for which weighting is desired can be controlled by applying a strong positive voltage to the word line WL and bit line BL. For example, assuming that the word line WL and the bit line BL are each 4V, when updating the forward region, only the forward region can be updated by applying high V_{GS} (4V) and low V_{GD} (0V).

FIG. 5B is a graph for explaining controlling only the ambipolar region. In this case, only the ambipolar region can be controlled by applying a strong negative voltage to the word line WL and a strong positive voltage to the bit line BL.

Through this, it can be seen that the forward region and ambipolar region can be controlled differently.

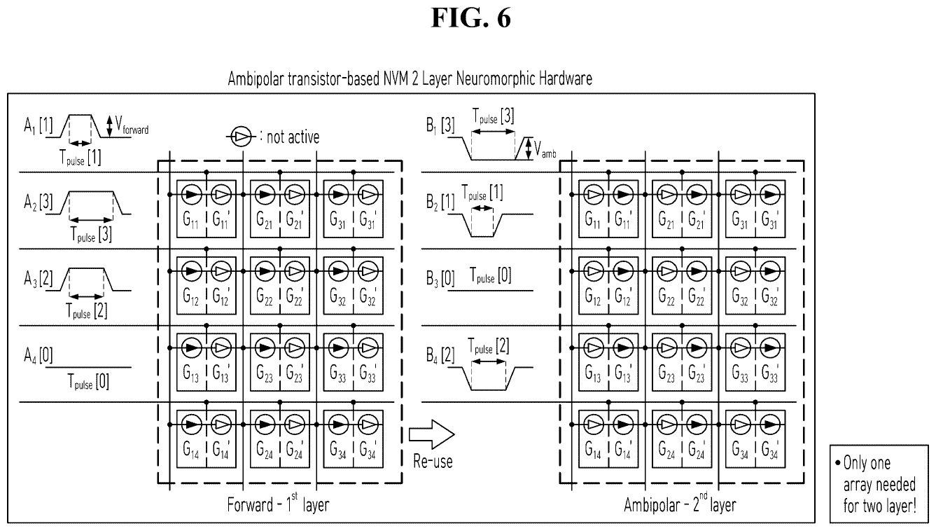

FIG. 6 is a diagram for explaining a neuromorphic hardware structure according to one embodiment of the present disclosure, and is a multi-layer artificial neural network processing neuromorphic hardware structure composed of ambipolar transistors with weight implantation completed.

The neuromorphic hardware of the present disclosure uses the ambipolar transistor to represent different weights through the forward region and the ambipolar region. Accordingly, two-layer artificial neural network operation is possible.

Referring to FIG. 6, the first layer operation can be performed using the weights of the forward region, and then the second layer operation can be performed using the weights of the ambipolar region. To implement a conventional two-layer artificial neural network, an array using two NVM devices is required as shown in FIG. 2, but in the present disclosure, it is possible to design neuromorphic hardware that can perform two-layer operation using one array, i.e., that is capable of multi-layer artificial neural network processing.

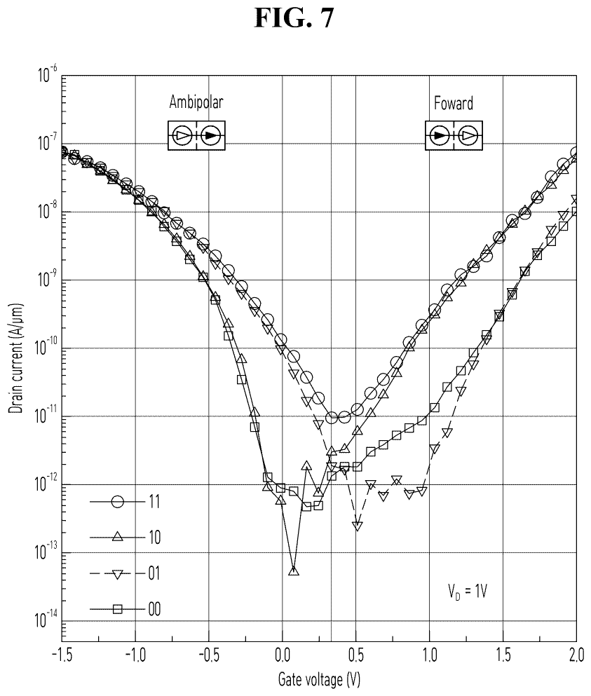

FIG. 7 is a diagram showing individual weight measurement results by two current mechanisms of the ambipolar transistor, where the ambipolar transistor is a silicon-based ferroelectric tunneling transistor (FeTFET).

Referring to FIG. 7, it can be seen that as a result of implanting the weights of the two regions (forward region and ambipolar region) separately through the weight implantation method described in FIG. 4, the highest weight ‘l’ and the lowest weight ‘0’ of each region can be implanted independently, and read and multiply operations are possible. Through this, it can be seen that multi-layer artificial neural network processing neuromorphic hardware operation is possible and can be applied not only to FeTFETs but also to various types of ambipolar transistor-based non-volatile memory devices.

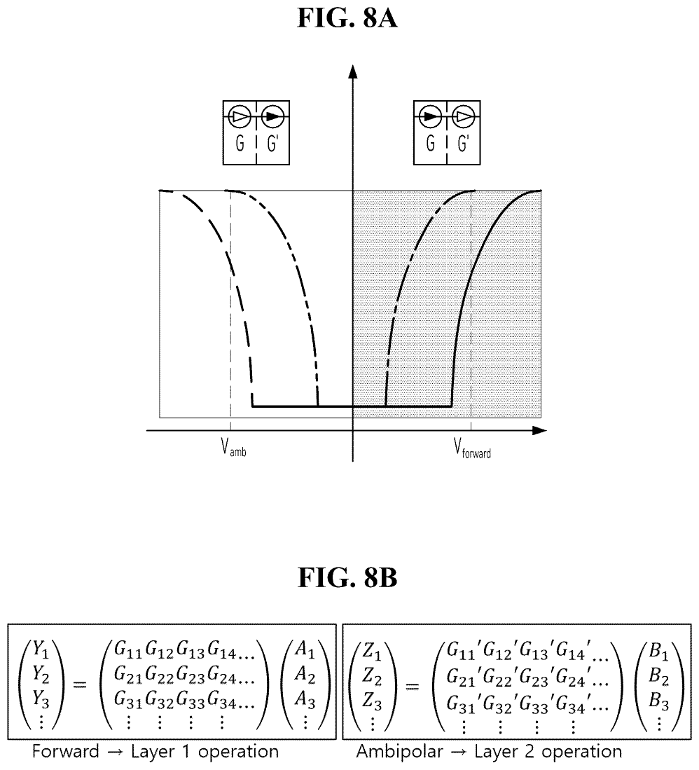

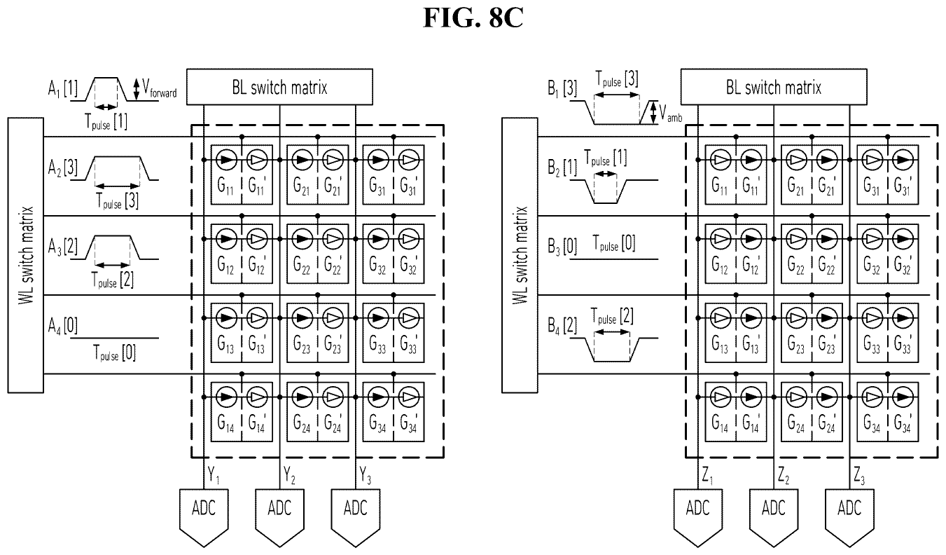

FIGS. 8A to 8C are diagrams for explaining the neuromorphic hardware structure and operation method according to one embodiment of the present disclosure. FIG. 8A shows the multi-bit FeTFET operation method, FIG. 8B shows weight extraction for multi-layer operation, and FIG. 8C is a diagram to explain the neuromorphic hardware structure and operation method.

The neuromorphic hardware according to the present disclosure has a multi-layer artificial neural network processing structure using ambipolar transistors disposed in an array of non-volatile memory formed along a plurality of bit lines (BL) and a plurality of word lines (WL). A neuromorphic device with such a hardware structure can perform a multi-layer artificial neural network operation by implanting a first weight in a first region of the ambipolar transistor, implanting a second weight in a second region of the ambipolar transistor, performing a first layer operation with the current in the first region and the implanted first weight, and performing a second layer operation with the current in the second region and the implanted second weight.

More specifically, first, as shown in FIG. 8A, the ambipolar transistor has two different current regions in the forward region and the ambipolar region, so it can be seen from the current characteristics that the weighted-voltage product operation (G*V) is possible by reading the current in each region.

Then, the weights of the multi-layer artificial neural network extracted through software can be extracted, as shown in FIG. 8B. The extracted weights are implanted in one ambipolar transistor array through the weight implantation method described in FIG. 4. The first layer operation is performed using the weight of the forward region, and the second layer operation is performed using the weight of the ambipolar region. In this case, the magnitude of the input signal can be adjusted through the voltage time (Tₚᵤₗₛₑ), and the final operation result can be obtained by sensing the current through the ADC. In the present embodiment, since the same bit line switch matrix (BL switch matrix), ADC, and word line switch matrix (WL switch matrix), DAC, and PWM operation method are used for each layer operation, the number of driving circuits and the number of additional weighting cells can be reduced, which dramatically reduces the overall chip area and power consumption.

In addition, although the artificial neural network is described as ADC for understanding, it can also be utilized in a spiking neural network application (SNN) to reduce the number of output neurons, and can also be applied to various artificial neural network neuromorphic hardware structures.

As described above, when computing data of a multi-layer artificial neural network using the ambipolar transistor-based NVM array, the number of devices can be reduced by half, resulting in very high integration, and the number of input/output stages, such as analog-to-digital converters, digital-to-analog converters (DACs), and neuron circuits, can also be reduced by half, resulting in a very large area reduction.

In addition, the present disclosure can be applied to various neuromorphic hardware structures since it can utilize not only a specific ambipolar transistor but also a variety of ambipolar transistors. Therefore, through the present disclosure, the integration and performance of neuromorphic hardware can be greatly improved.

In the multi-layer artificial neural network computation, the present disclosure enables two-layer operation with one array, so it can be configured in a much smaller area than existing neuromorphic hardware. The number of ADCs that sense the output value, which accounts for the most power consumption in neuromorphic hardware operations, can be reduced by half, greatly increasing power efficiency. These advantages are essential technology for artificial neural network technologies, such as the recent GPT-4, where the number of parameters and the number of multiple layers is increasing.

While the present disclosure has been described above with reference to the preferred embodiments, it will be understood by those skilled in the art that various modifications and changes can be made to the present disclosure without departing from the idea and scope of the present disclosure as defined in the following claims.

### DESCRIPTION OF REFERENCE SYMBOLS

100: Neuromorphic device
WL: word line BL: bit line

1. A neuromorphic device comprising:
a plurality of bit lines;
a plurality of word lines; and
a non-volatile memory array including an ambipolar transistor disposed in a region where the bit lines and the word lines intersect.

2. The neuromorphic device of claim 1, wherein the non-volatile memory array uses the ambipolar transistor as a synaptic device.

3. The neuromorphic device of claim 1, wherein the non-volatile memory array performs two-layer operation by implanting different weights in two current regions present in the ambipolar transistor.

4. The neuromorphic device of claim 1, wherein the non-volatile memory array alternately applies specific voltages of first and second polarities to word lines and bit lines connected to specific synaptic devices among the plurality of bit lines and the plurality of word lines to perform weight implantation for multi-layer learning.

5. The neuromorphic device of claim 1, wherein the non-volatile memory array applies a specific voltage of a first polarity to a forward region of the ambipolar transistor, and applies a specific voltage of a second polarity different from the first polarity to an ambipolar region of the ambipolar transistor to implant different weights in the respective regions.

6. The neuromorphic device of claim 1, wherein the non-volatile memory array performs weight implantation by applying a specific voltage to a word line and a bit line connected to a target device among the plurality of bit lines and the plurality of word lines, and allowing the remaining word lines and bit lines to be grounded or floating.

7. A multi-layer artificial neural network processing neuromorphic device, comprising:
a plurality of bit lines arranged to extend along a first direction;
a plurality of word lines extending along a second direction perpendicular to the first direction; and
a plurality of synaptic devices located in regions where the bit lines and the word lines intersect,
wherein the synaptic device includes an ambipolar transistor composed of two current regions.

8. The neuromorphic device of claim 7, wherein the ambipolar transistor includes a tunneling transistor or a ferroelectric tunneling transistor.

9. The neuromorphic device of claim 7, wherein the ambipolar transistor has two or more different current mechanisms depending on a gate voltage, and includes a forward region and an ambipolar region with symmetrical current characteristics as a function of voltage.

10. The neuromorphic device of claim 9, wherein in a non-volatile memory device based on the ambipolar transistor, the forward region and the ambipolar region are each controlled to store two weights in one synaptic device.

11. The neuromorphic device of claim 9, wherein when different weights are stored in the forward region and the ambipolar region, two analog vector matrix multiplications (VMM) are performed in one synapse array.

12. An operation method of a neuromorphic device using an ambipolar transistor disposed in an array of non-volatile memory formed along a plurality of bit lines and a plurality of word lines, the method comprising:
implanting a first weight in a first region of the ambipolar transistor;
implanting a second weight in a second region of the ambipolar transistor;
performing a first layer operation using a current in the first region and the implanted first weight; and
performing a second layer operation using a current in the second region and the implanted second weight.

13. The method of claim 12, wherein the ambipolar transistor has two or more different current mechanisms depending on a gate voltage, and includes a forward region and an ambipolar region with symmetrical current characteristics as a function of voltage.

14. The method of claim 12, wherein the implanting of the first weight includes applying a specific voltage of a first polarity to a gate of the ambipolar transistor to perform weight implantation in one of a forward region and an ambipolar region of the ambipolar transistor.

15. The method of claim 14, wherein the implanting of the second weight includes applying a specific voltage of a second polarity to the gate of the ambipolar transistor to perform weight implantation in the remaining region of the ambipolar transistor.

16. The method of claim 12, wherein in the implanting of the first weight and the implanting of the second weight, two weights are stored in one synaptic device by controlling a forward region and an ambipolar region of the ambipolar transistor.

17. The method of claim 12, wherein the performing of the first layer operation includes calculating with a weight of a forward region of the ambipolar transistor and adjusting a magnitude of an input signal through a voltage time applied to a gate of the ambipolar transistor.

18. The method of claim 13, wherein the performing of the second layer operation includes calculating with a weight of an ambipolar region of the ambipolar transistor and adjusting a magnitude of an input signal through a voltage time applied to a gate of the ambipolar transistor.

19. The method of claim 12, wherein the performing of the first layer operation includes performing a product operation of weight and voltage by reading a current in a forward region of the ambipolar transistor, and obtaining an operation result by sensing a current through an analog-to-digital converter.

20. The method of claim 12, wherein the performing of the second layer operation includes performing a product operation of weight and voltage by reading a current in an ambipolar region of the ambipolar transistor, and obtaining an operation result by sensing a current through an analog-to-digital converter.
